(19) United States
(12) Patent Application Publication
(10) Pub. No.: US 2026/0354194 A1
(43) Pub. Date: Nov. 5, 2026

(54) LAMINATED-STRUCTURE MANUFACTURING APPARATUS AND METHOD OF MANUFACTURING LAMINATED STRUCTURE

(71) Applicant: EBARA CORPORATION, Tokyo (JP)

(72) Inventors: Kazuhiro TAJIMA, Tokyo (JP); Masayuki SATAKE, Tokyo (JP)

(21) Appl. No.: 19/140,084

(22) PCT Filed: Nov. 20, 2023
(86) PCT No.: PCT/JP2023/041587

§ 371 Date: Jun. 17, 2025

(30) Foreign Application Priority Data
Dec. 23, 2022 (JP) 2022-206245

(51) Int. Cl. H10W 42/00; H10D 88/00; H10P 72/00; H10P 72/50

(52) U.S. Cl. CPC H10W 42/121; H10D 88/01; H10P 72/0441; H10P 72/50

(57) ABSTRACT

The present application relates to a technique of applying filler to a gap between edge portions of substrates constituting a laminated substrate. A manufacturing apparatus includes: a substrate holding device configured to hold and rotate the laminated substrate; an application device configured to apply the filler to a gap between an edge portion of the first substrate and an edge portion of the second substrate, the application device having a filler emitting port configured to emit the filler; a relative moving mechanism configured to move at least one of the application device and the substrate holding device; a position detecting device configured to detect position information on an application target point in the gap; and an operation controller configured to instruct the relative moving mechanism to adjust a relative position of the filler emitting port and the application target point based on the detected position information.

### TECHNICAL FIELD

The present invention relates to a laminated-structure manufacturing apparatus and a method of manufacturing a laminated structure for suppressing cracking and chipping of a laminated substrate manufactured by bonding substrates, and more particularly to a technique of applying filler to a gap between edge portions of the substrates constituting the laminated substrate.

### BACKGROUND ART

In recent years, in order to achieve higher density and higher functionality in semiconductor devices, three-dimensional packaging technology, in which substrates are laminated and integrated three-dimensionally, has been developed. For example, in the three-dimensional packaging technology, a device surface of a first substrate on which integrated circuits and electrical wires are formed is bonded to a device surface of a second substrate on which integrated circuits and electrical wires are formed. After the first substrate is bonded to the second substrate, the second substrate is thinned by a polishing apparatus or a grinding apparatus. In this manner, integrated circuits can be stacked in a direction perpendicular to the device surfaces of the first substrate and the second substrate.

In the three-dimensional packaging technology, three or more substrates may be bonded to each other. For example, a third substrate may be bonded to the second substrate after the second substrate bonded to the first substrate has been thinned, and then the third substrate may be thinned. In this specification, a substrate in a form of substrates bonded to each other may be referred to as a “laminated substrate”.

Generally, an edge portion of a substrate is polished in advance to have a rounded shape or a beveled shape in order to prevent cracking or chipping of the edge portion. When the second substrate having such a shape is grinded (thinned), an acute edge is formed in the second substrate as a result of grinding. This acute edge (hereinafter referred to as a knife-edge portion) is constituted of a grinded back surface and a circumferential surface of the second substrate. Such a knife-edge portion is likely to be chipped by a physical contact, and the laminated substrate itself may be broken during transportation of the laminated substrate. Furthermore, insufficient bonding between the first substrate and the second substrate may cause the second substrate to be cracked during grinding.

Thus, a filler is applied to the edge portion of the laminated substrate before the second substrate is grinded in order to prevent the knife-edge portion from cracking or chipping. The filler is applied to a gap between an edge portion of the first substrate and an edge portion of the second substrate. The filler can support the knife-edge portion that has been formed after the second substrate is grinded, and can prevent cracking or chipping of the knife-edge portion.

### CITATION LIST

### Patent Literature

Patent document 1: Japanese laid-open patent publication No. 2022-38834

### SUMMARY OF INVENTION

### Technical Problem

Application of the filler to the gap between the edge portion of the first substrate and the edge portion of the second substrate is performed by rotating the laminated substrate and emitting the filler from a filler emitting port of an application device. In order to appropriately apply the filler around the entire circumference of the gap of the laminated substrate, it is necessary to arrange the filler emitting port at an appropriate position relative to an application target point in the gap. The position of the filler emitting port relative to the gap between the edge portion of the first substrate and the edge portion of the second substrate is adjusted according to visual check by an operator. However, the gap between the edge portion of the first substrate and the edge portion of the second substrate is slight, so that precise adjustment is required. Therefore, there are limits to the visual adjustment by the operator.

Furthermore, if the laminated substrate is eccentric with respect to a rotation center of a substrate holding device configured to hold the laminated substrate, the position of the application target point in a radial direction of the laminated substrate may fluctuate during application of the filler. In addition, due to a surface deflection of the laminated substrate caused by the rotation of the laminated substrate, the position of the application target point in a thickness direction of the laminated substrate may fluctuate during application of the filler. In order to appropriately apply the filler to the entire circumference of the gap of the laminated substrate, it is necessary to change the position of the filler emitting port to follow the fluctuations in the position of the application target point due to the surface deflection or the eccentricity.

Thus, the present invention provides a laminated-structure manufacturing apparatus and a method of manufacturing a laminated structure capable of appropriately applying a filler to a gap between an edge portion of a first substrate and an edge portion of a second substrate.

### Solution to Problem

In an embodiment, there is provided a laminated-structure manufacturing apparatus for applying filler to a laminated substrate having a first substrate and a second substrate bonded to each other to manufacture a laminated structure, comprising: a substrate holding device configured to hold and rotate the laminated substrate; an application device configured to apply the filler to a gap between an edge portion of the first substrate and an edge portion of the second substrate, the application device having a filler emitting port configured to emit the filler; a relative moving mechanism configured to move at least one of the application device and the substrate holding device; a position detecting device configured to detect position information on an application target point in the gap; and an operation controller configured to instruct the relative moving mechanism to adjust a relative position of the filler emitting port and the application target point based on the detected position information.

In an embodiment, the position detecting device is configured to detect the position information including a position of the application target point in a radial direction of the laminated substrate and a position of the application target point in a thickness direction of the laminated substrate.

In an embodiment, the position detecting device includes an edge-shape detector configured to detect a shape of an edge portion of the laminated substrate.

In an embodiment, the position detecting device includes an eccentricity detector configured to detect the position of the application target point in the radial direction of the laminated substrate, and a surface-deflection detector configured to detect the position of the application target point in the thickness direction of the laminated substrate.

In an embodiment, the position detecting device includes an image generating device configured to generate an image of an edge portion of the laminated substrate.

In an embodiment, the position detecting device is configured to detect position information on multiple application target points in the gap arranged along a circumferential direction of the laminated substrate, and the operation controller is configured to instruct the relative moving mechanism to adjust a relative position of the filler emitting port and each of the multiple application target points based on the detected position information during application of the filler to the gap of the laminated substrate when the laminated substrate is rotated.

In an embodiment, the position detecting device is configured to detect the position information on the application target point when the application target point is located upstream of the filler emitting port in a rotating direction of the laminated substrate.

In an embodiment, there is provided a method of manufacturing a laminated structure by applying filler to a laminated substrate having a first substrate and a second substrate bonded to each other, comprising: detecting position information on an application target point in a gap between an edge portion of the first substrate and an edge portion of the second substrate; adjusting a relative position of a filler emitting port configured to emit the filler and the application target point based on the detected position information; and applying the filler to the gap while the laminated substrate is rotated.

In an embodiment, detecting the position information comprises detecting the position information including a position of the application target point in a radial direction of the laminated substrate and a position of the application target point in a thickness direction of the laminated substrate.

In an embodiment, detecting the position information includes detecting a shape of an edge portion of the laminated substrate by an edge-shape detector.

In an embodiment, detecting the position information includes detecting the position of the application target point in the radial direction of the laminated substrate by an eccentricity detector, and detecting the position of the application target point in the thickness direction of the laminated substrate by a surface-deflection detector.

In an embodiment, detecting the position information includes generating an image of an edge portion of the laminated substrate by an image generating device.

In an embodiment, detecting the position information comprises detecting position information on multiple application target points in the gap arranged along a circumferential direction of the laminated substrate when each of the multiple application target points is located upstream of the filler emitting port in a rotating direction of the laminated substrate during application of the filler to the gap, and adjusting the relative position comprises adjusting a relative position of the filler emitting port and each of the multiple application target points based on the detected position information during application of the filler to the gap.

In an embodiment, detecting the position information comprises detecting position information on multiple application target points in the gap arranged along a circumferential direction of the laminated substrate while the laminated substrate is rotated before the filler is applied to the gap, and adjusting the relative position comprises adjusting a relative position of the filler emitting port and each of the multiple application target points based on the detected position information during application of the filler to the gap.

### Advantageous Effects of Invention

According to the present invention, the relative position of the filler emitting port of the application device and the application target point can be adjusted based on the position information on the application target point detected by the position detecting device. As a result, the relative position of the filler emitting port and the application target point can be maintained at a predetermined target relative position, so that the filler can be appropriately applied to the gap between the edge portion of the first substrate and the edge portion of the second substrate.

### BRIEF DESCRIPTION OF DRAWINGS

FIG. 1A is a cross-sectional view showing an example of an edge portion of a laminated substrate to be processed;

FIG. 1B is a cross-sectional view showing an example of the edge portion of the laminated substrate to which filler has been applied;

FIG. 1C is a cross-sectional view showing an example of the edge portion of the laminated substrate that has been thinned after the filler is applied;

FIG. 2 is a front view showing an embodiment of a laminated-structure manufacturing apparatus;

FIG. 3 is a side view of the laminated-structure manufacturing apparatus shown in FIG. 2;

FIG. 4 is a schematic diagram showing an embodiment of an application device; FIG. 5 is a schematic diagram showing a manner in which an edge-shape detector detects position information on an application target point in a gap between an edge portion of a first substrate and an edge portion of a second substrate;

FIG. 6 is a diagram showing a shape of an edge portion of a laminated substrate detected by the edge-shape detector;

FIG. 7 is a flowchart illustrating an embodiment of a method of manufacturing the laminated structure;

FIG. 8 is a flowchart illustrating another embodiment of the method of manufacturing the laminated structure;

FIG. 9 is a front view showing another embodiment of the laminated-structure manufacturing apparatus;

FIG. 10 is a side view of the laminated-structure manufacturing apparatus shown in FIG. 9;

FIG. 11 is a front view showing still another embodiment of the laminated-structure manufacturing apparatus;

FIG. 12 is a side view of the laminated-structure manufacturing apparatus shown in FIG. 11;

FIG. 13 is a front view showing still another embodiment of the laminated-structure manufacturing apparatus;

FIG. 14 is a diagram showing an example of an image of the edge portion of the laminated substrate generated by an image generating device; and

FIG. 15 is a side view showing an embodiment of the laminated-structure manufacturing apparatus including a substrate-holding-device moving mechanism.

### DESCRIPTION OF EMBODIMENTS

Hereinafter, embodiments of the present invention will be described in detail with reference to the drawings.

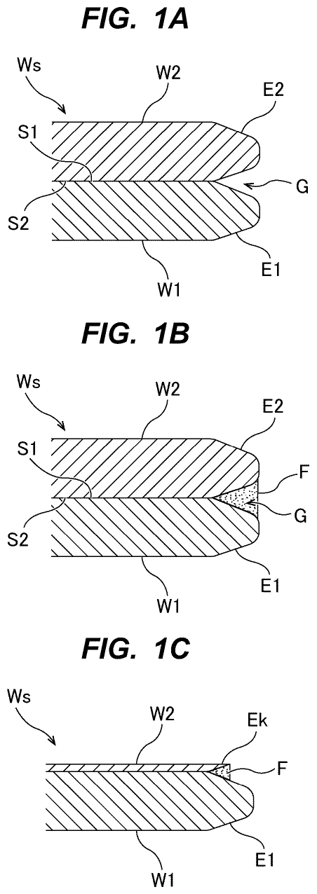

FIG. 1A is a cross-sectional view showing an example of an edge portion of a laminated substrate Ws to be processed. As shown in FIG. 1A, the laminated substrate Ws includes a first substrate W1 and a second substrate W2 bonded to each other. Each of the first substrate W1 and the second substrate W2 for use in this embodiment has a circular shape.

An edge portion E1 of the first substrate W1 is a portion constituting an outermost circumferential surface inclined with respect to a bonding surface (e.g., a device surface) S1 of the first substrate W1. More specifically, the edge portion E1 of the first substrate W1 has a rounded shape or a beveled shape. Similarly, an edge portion E2 of the second substrate W2 is a portion constituting an outermost circumferential surface inclined with respect to a bonding surface (e.g., a device surface) S2 of the second substrate W2. More specifically, the edge portion E2 of the second substrate W2 has a rounded shape or a beveled shape. Each of the edge portions E1 and E2 may be referred to a bevel portion. A gap G is formed between the edge portion E1 of the first substrate W1 and the edge portion E2 of the second substrate W2. The edge portion of the laminated substrate Ws includes the edge portion E1 of the first substrate W1 and the edge portion E2 of the second substrate W2.

FIG. 1B is a cross-sectional view showing an example of the edge portion of the laminated substrate Ws to which a filler F has been applied. In this specification, the laminated substrate Ws to which the filler F has been applied may be referred to as a laminated structure. The filler F is applied to the gap G between the edge portion E1 of the first substrate W1 and the edge portion E2 of the second substrate W2. This gap G is formed over the entire circumference of the laminated substrate Ws, and has an approximately triangular cross section. The filler F is applied so as to fill this gap G.

FIG. 1C is a cross-sectional view showing an example of the edge portion of the laminated substrate Ws that has been thinned after the filler F is applied. As a result of this thinning process, a knife-edge portion Ek is formed in the edge portion E2 of the second substrate W2. Since the knife-edge portion Ek is held (or supported) by the filler F, the knife-edge portion Ek is prevented from cracking or chipping.

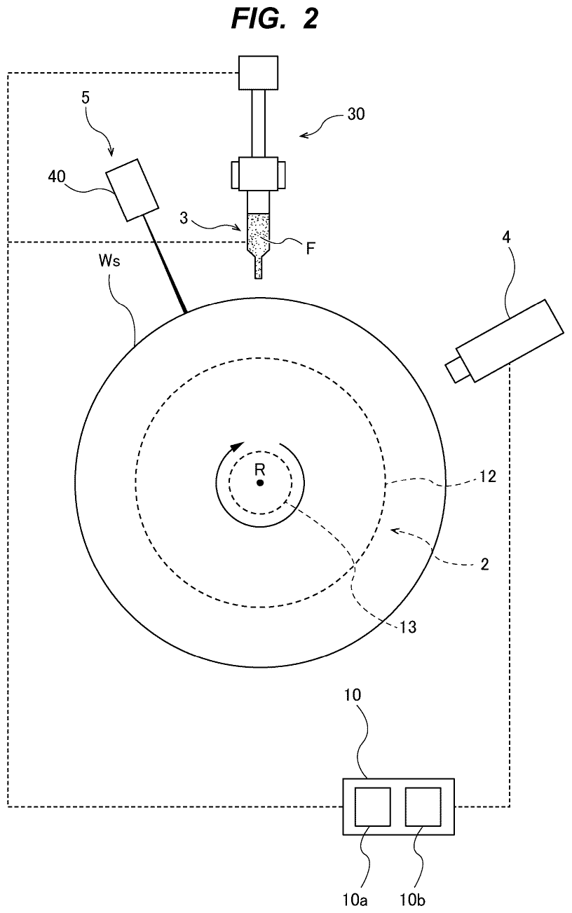

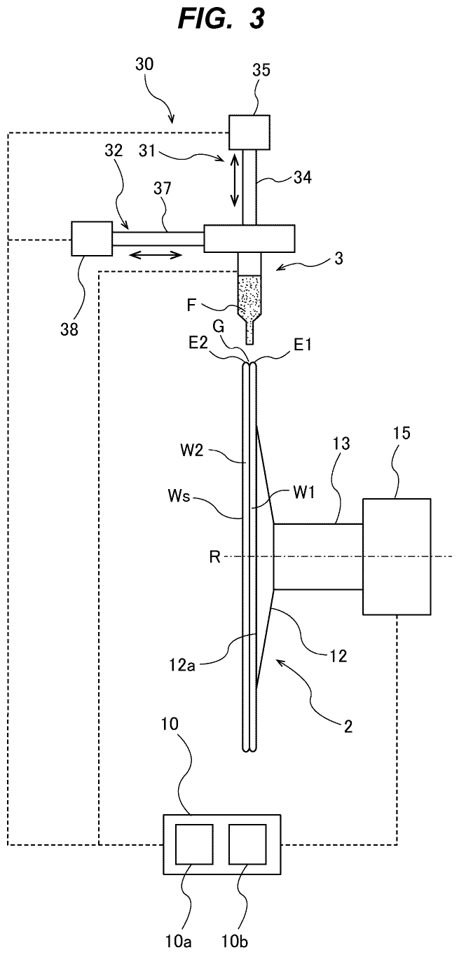

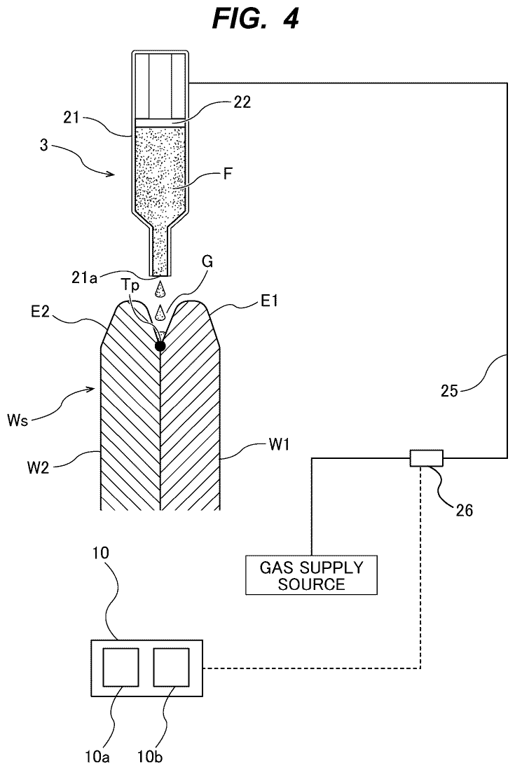

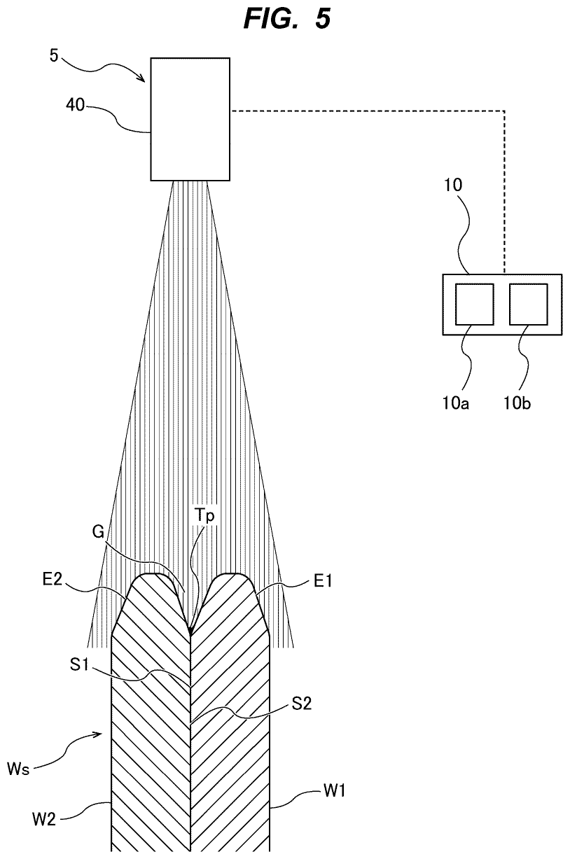

FIG. 2 is a front view showing an embodiment of a laminated-structure manufacturing apparatus, and FIG. 3 is a side view of the laminated-structure manufacturing apparatus shown in FIG. 2. The laminated-structure manufacturing apparatus is an apparatus for applying the filler F to the laminated substrate Ws having the first substrate W1 and the second substrate W2 which have been bonded to manufacture the laminated structure. The laminated-structure manufacturing apparatus includes a substrate holding device 2 configured to hold the laminated substrate Ws in a vertical posture and rotate the laminated substrate Ws held thereon, an application device 3 configured to apply the filler F, and a curing device 4 configured to cure the applied filler F.

The substrate holding device 2 includes a holding stage 12 configured to hold a back surface of the laminated substrate Ws, a rotating shaft 13 coupled to a central portion of the holding stage 12, and a rotating mechanism 15 configured to rotate the holding stage 12 and the rotating shaft 13. The holding stage 12 is configured to hold the back surface of the laminated substrate Ws by vacuum suction. As shown in FIG. 3, the holding stage 12 has a holding surface 12a that is perpendicular to a horizontal plane. The laminated substrate Ws is held by the holding stage 12 such that a flat portion of the laminated substrate Ws is perpendicular to the horizontal plane. Therefore, the laminated substrate Ws is held in the vertical posture by the substrate holding device 2.

The rotation mechanism 15 includes a motor (not shown). The rotation mechanism 15 is configured to rotate the holding stage 12 and the laminated substrate Ws held by the holding stage 12 together in a direction shown by an arrow about a rotation axis R of the substrate holding device 2.

In one embodiment, the substrate holding device 2 may include, instead of the holding stage 12, multiple (e.g., four) rollers (not shown) which can contact a periphery of the laminated substrate Ws. The laminated substrate Ws may be held by these rollers such that the flat portion of the laminated substrate Ws is perpendicular to the horizontal plane. In this case, the substrate holding device 2 includes, instead of the rotating shaft 13 and the rotating mechanism 15, a roller rotating mechanism (not shown) configured to rotate the rollers about their respective own axes at the same speed in the same direction. The rollers are rotated by the roller rotating mechanism, so that the laminated substrate Ws is rotated about the rotation center of the substrate holding device 2.

The application device 3 is located radially outwardly of the laminated substrate Ws held by the substrate holding device 2. The application device 3 is located above the laminated substrate Ws and is arranged so as to face the gap G of the laminated substrate Ws. The application device 3 is configured to apply the filler F to the gap G between the edge portion E1 of the first substrate W1 and the edge portion E2 of the second substrate W2 of the laminated substrate Ws. Application of the filler F by the application device 3 is performed while the laminated substrate Ws is rotated by the substrate holding device 2. The filler F may be applied while the laminated substrate Ws is rotated multiple times depending on a total amount of the filler F to be applied.

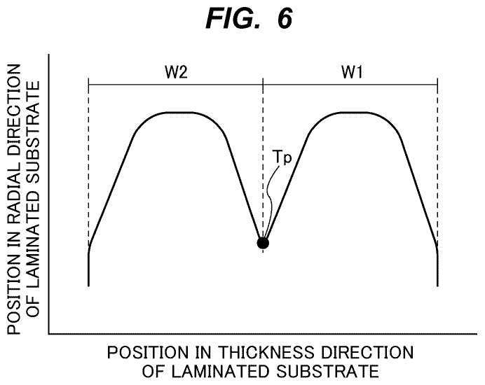

FIG. 4 is a schematic diagram showing an embodiment of the application device 3. The application device 3 includes a syringe 21 for injecting the filler F, and a piston 22 that can reciprocate in the syringe 21. The syringe 21 has a hollow structure and is configured to be filled with the filler F therein. The piston 22 is arranged in the syringe 21. The syringe 21 has, at its distal end, a filler emitting port 21a configured to emit the filler F. The distal end of the syringe 21 including the filler emitting port 21a may be configured to be detachable. An appropriate shape of the filler emitting port 21a is selected based on physical properties (e.g., viscosity, etc.) of the filler F to be applied.

The application device 3 is coupled to a gas supply source via a gas supply line 25. When gas (e.g., dry air or nitrogen gas) is supplied from the gas supply source into the syringe 21, the piston 22 moves forward in the syringe 21. The forward movement of the piston 22 causes the filler F in the syringe 21 to be emitted through the filler emitting port 21a. A pressure regulator 26 is disposed in the gas supply line 25. The pressure regulator 26 can regulate an amount of the filler F to be emitted from the filler emitting port 21a per unit time by regulating a pressure of the gas to be supplied from the gas supply source to the application device 3. When the application device 3 emits the filler F, the filler F drops toward the gap G of the laminated substrate Ws, and as a result, the filler F can be applied to the gap G of the laminated substrate Ws.

In one embodiment, the application device 3 may include a screw feeder instead of the combination of the syringe 21 and the piston 22.

The filler emitting port 21a is arranged so as to face an application target point Tp in the gap G of the laminated substrate Ws by a relative moving mechanism configured to adjust a relative position of the filler emitting port 21a and the application target point Tp, which will be described in detail later. The application target point Tp is a target point onto which the filler F emitted from the filler emitting port 21a drops. A position of the application target point Tp is determined in advance based on a shape of the laminated substrate Ws (i.e., shapes of the first substrate W1 and the second substrate W2), properties of the filler F, etc. The application target points Tp are continuously located in the gap G along a circumferential direction of the laminated substrate Ws when being rotated. In this embodiment, the application target point Tp is the deepest portion in the gap G between the edge portion E1 of the first substrate W1 and the edge portion E2 of the second substrate W2. In one embodiment, when thicknesses of the first substrate W1 and the second substrate W2 are the same, the application target point Tp may be located at the midpoint in a thickness direction of the laminated substrate Ws.

As shown in FIG. 2, the curing device 4 is located radially outwardly of the laminated substrate Ws held by the substrate holding device 2, and is arranged so as to face the gap G of the laminated substrate Ws. The curing device 4 is disposed downstream of the application device 3 in a rotating direction of the laminated substrate Ws. The curing device 4 is configured to cure the filler F that has been applied to the laminated substrate Ws by the application device 3. Curing of the filler F by the curing device 4 is performed while the laminated substrate Ws is rotated by the substrate holding device 2. In this embodiment, the filler F has thermosetting property. An example of such filler is a thermosetting resin.

The filler F includes a binder, a solvent, and particles. The particles are dispersed in the binder dissolved in the solvent. For example, a composition of the filler F is determined from a type of the binder, an amount of the solvent, an amount of the particles, or a size of each of the particles. Examples of the binder include inorganic binder containing alkali metal silicate, organic binder made of silicone resin or epoxy resin, and an inorganic-organic hybrid binder. The particles are, for example, particles of silica or alumina. The particles are mixed into the binder to increase a volume of the filler F and to adjust a viscosity of the filler F. In order to reduce the viscosity of the filler F, the particles may not be contained in the filler F.

The curing device 4 in this embodiment is an air heater, which is configured to emit hot air toward the filler F applied to the laminated substrate Ws. The filler F heated with the hot air is cured by a crosslinking reaction. When the filler F contains a solvent, the solvent is volatilized by the heating. The curing device 4 is not limited to the air heater, and may be a lamp heater or other configuration as long as the curing device 4 can heat and cure the filler F.

In this embodiment, the filler F has thermosetting property, while in one embodiment, the filler F may have ultraviolet curable property. In this case, the curing device 4 may be a UV irradiation device configured to cure the filler F by emitting ultraviolet ray. When the filler F contains a solvent, the curing device 4 may heat the filler F to volatilize the solvent with an air heater or the like, in addition to the UV irradiation device.

The laminated-structure manufacturing apparatus includes the relative moving mechanism configured to move at least one of the application device 3 and the substrate holding device 2. In this embodiment, the laminated-structure manufacturing apparatus includes an application-device moving mechanism 30 configured to move the application device 3 as the relative moving mechanism. As shown in FIG. 3, the application-device moving mechanism 30 includes a first application-device moving mechanism 31 configured to move the application device 3 in a radial direction of the laminated substrate Ws, and a second application-device moving mechanism 32 configured to move the application device 3 in the thickness direction of the laminated substrate Ws. The first application-device moving mechanism 31 and the second application-device moving mechanism 32 are coupled to the application device 3.

The first application-device moving mechanism 31 is configured to move the application device 3 in a direction perpendicular to the rotation axis R of the substrate holding device 2. The second application-device moving mechanism 32 is configured to move the application device 3 in a direction parallel to the rotation axis R of the substrate holding device 2. Examples of the first application-device moving mechanism 31 and the second application-device moving mechanism 32 include a combination of a linear moving mechanism (such as a ball screw mechanism or a cylinder mechanism) and a motor (such as a servo motor or a stepping motor), and a linear moving electric actuator (such as a linear motor).

The first application-device moving mechanism 31 of this embodiment includes a first linear moving mechanism 34 coupled to the application device 3, and a first motor 35 coupled to the first linear moving mechanism 34. The first motor 35 and the first linear moving mechanism 34 are configured to move the application device 3 in the radial direction of the laminated substrate Ws. More specifically, the first motor 35 is configured to actuate the first linear moving mechanism 34 to thereby move the filler emitting port 21a of the application device 3 toward and away from the gap G of the laminated substrate Ws. The second application-device moving mechanism 32 of this embodiment includes a second linear moving mechanism 37 coupled to the application device 3, and a second motor 38 coupled to the second linear moving mechanism 37. The second motor 38 and the second linear moving mechanism 37 are configured to move the application device 3 in the thickness direction of the laminated substrate Ws. More specifically, the second motor 38 is configured to actuate the second linear moving mechanism 37 to thereby move the filler emitting port 21a of the application device 3 in the thickness direction of the laminated substrate Ws.

The laminated-structure manufacturing apparatus further includes an operation controller 10 configured to control operations of the substrate holding device 2, the curing device 4, the pressure regulator 26, and the application-device moving mechanism 30 (i.e., the first application-device moving mechanism 31 and the second application-device moving mechanism 32). The substrate holding device 2, the curing device 4, the pressure regulator 26, and the application-device moving mechanism 30 (i.e., the first application-device moving mechanism 31 and the second application-device moving mechanism 32) are electrically coupled to the operation controller 10.

The operation controller 10 is composed of at least one computer. The operation controller 10 includes a memory 10a storing programs therein, and a processor 10b configured to perform arithmetic operations according to instructions contained in the programs. The memory 10a includes a main memory, such as a random-access memory (RAM), and an auxiliary memory, such as a hard disk drive (HDD) or a solid state drive (SSD). Examples of the processor 10b include a CPU (central processing unit) and a GPU (graphic processing unit). However, the specific configuration of the operation controller 10 is not limited to these examples.

During application of the filler F to the gap of the laminated substrate Ws, it is necessary to change the position of the filler emitting port 21a of the application device 3 to follow fluctuations in the position of the application target point Tp due to a surface deflection or an eccentricity of the laminated substrate Ws. Thus, the laminated-structure manufacturing apparatus further includes a position detecting device 5 configured to detect position information on the application target point Tp in the gap G between the edge portion E1 of the first substrate W1 and the edge portion E2 of the second substrate W2. The position detecting device 5 is configured to detect the position information including a position of the application target point Tp in the radial direction of the laminated substrate Ws and a position of the application target point Tp in the thickness direction of the laminated substrate Ws. The position detecting device 5 of this embodiment includes an edge-shape detector 40 configured to detect a shape of the edge portion of the laminated substrate Ws.

As shown in FIG. 2, the edge-shape detector 40 is located radially outwardly of the laminated substrate Ws held by the substrate holding device 2, and is arranged so as to face the gap G of the laminated substrate Ws. The edge-shape detector 40 is disposed upstream of the application device 3 in the rotating direction of the laminated substrate Ws. A position of the edge-shape detector 40 is fixed. The position detecting device 5 (the edge-shape detector 40 in this embodiment) is configured to detect the position information on the application target point Tp when the application target point Tp is located upstream of the filler emitting port 21a of the application device 3 in the rotating direction of the laminated substrate Ws.

FIG. 5 is a schematic diagram showing a manner in which the edge-shape detector 40 detects the position information on the application target point Tp in the gap G between the edge portion E1 of the first substrate W1 and the edge portion E2 of the second substrate W2. As shown in FIG. 5, the edge-shape detector 40 is configured to detect a shape of the edge portion of the laminated substrates Ws, i.e., shapes of the edge portion E1 of the first substrate W1 and the edge portion E2 of the second substrate W2. An example of the edge-shape detector 40 is a two-dimensional profile measuring device (e.g., a line sensor) that is a non-contact laser displacement sensor.

The edge-shape detector 40 has a light source (not shown), and a light-receiving element (not shown). The edge-shape detector 40 directs linear light (i.e., line-shaped laser light) from the light source to the edge portion E1 of the first substrate W1 and the edge portion E2 of the second substrate W2, and receives reflected light from the edge portion E1 of the first substrate W1 and the edge portion E2 of the second substrate W2 by the light-receiving element. A width of the linear light extends along the thickness direction of the laminated substrate Ws. The edge-shape detector 40 measures a surface height of the edge portion of the laminated substrate Ws along the thickness direction of the laminated substrate Ws based on the reflected light, and detects the shape of the edge portion of the laminated substrate Ws along the thickness direction of the laminated substrate Ws.

FIG. 6 is a diagram showing the shape of the edge portion of the laminated substrate Ws detected by the edge-shape detector 40. The detected shape of the edge portion of the laminated substrate Ws includes a shape of a valley representing the gap G between the edge portion E1 of the first substrate W1 and the edge portion E2 of the second substrate W2. Therefore, information on the position of the application target point Tp in the radial direction of the laminated substrate Ws and the position of the application target point Tp in the thickness direction of the laminated substrate Ws is included in the detected shape of the edge portion of the laminated substrate Ws. In this manner, the edge-shape detector 40 detects the position information on the application target point Tp (i.e., the position of the application target point Tp in the radial direction of the laminated substrate Ws and the position of the application target point Tp in the thickness direction of the laminated substrate Ws). In this embodiment, the application target point Tp is the deepest portion of the gap G appearing in the shape of the edge portion of the laminated substrate Ws, while in one embodiment, the application target point Tp may be the midpoint in the thickness direction of the laminated substrate Ws appearing in the shape of the edge portion of the laminated substrate Ws.

The position detecting device 5 (the edge-shape detector 40 in this embodiment) is electrically coupled to the operation controller 10. The position information on the application target point Tp (i.e., the position of the application target point Tp in the radial direction of the laminated substrate Ws and the position of the application target point Tp in the thickness direction of the laminated substrate Ws included in the shape of the edge portion of the laminated substrate Ws) detected by the edge-shape detector 40 is transmitted to the operation controller 10. The operation controller 10 is configured to instruct the application-device moving mechanism 30 (i.e., the first application-device moving mechanism 31 and the second application-device moving mechanism 32) to adjust the relative position of the filler emitting port 21a of the application device 3 and the application target point Tp such that the relative position of the filler emitting port 21a of the application device 3 and the application target point Tp coincides with a predetermined target relative position based on the detected position information on the application target point Tp.

More specifically, the operation controller 10 is configured to determine a current position of the application target point Tp based on the position information on the application target point Tp detected by the position detecting device 5 (the edge-shape detector 40 in this embodiment), and is configured to calculate a distance and a direction (i.e., a vector) from a reference position of the application target point Tp to the current position of the application target point Tp. Further, the operation controller 10 is configured to determine a target position of the application device 3 at which the relative position of the filler emitting port 21a and the application target point Tp coincides with the predetermined target relative position from the calculated distance and direction, and is configured to instruct the application-device moving mechanism 30 (i.e., the first application-device moving mechanism 31 and the second application-device moving mechanism 32) to move the application device 3 to the target position. As a result of such operations, the relative position of the filler emitting port 21a and the application target point Tp is maintained at the predetermined target relative position. The target relative position is a relative position at which the filler F is appropriately applied from the filler emitting port 21a to the gap G of the laminated substrate Ws, and is determined in advance based on experimental results, etc.

In this embodiment, just before the application target point Tp is located directly below the filler emitting port 21a of the application device 3, the operation controller 10 instructs the application-device moving mechanism 30 (i.e., the first application-device moving mechanism 31 and the second application-device moving mechanism 32) to move the application device 3. The operation controller 10 is configured to determine (calculate) a timing to cause the application-device moving mechanism 30 (i.e., the first application-device moving mechanism 31 and the second application-device moving mechanism 32) to move the application device 3 based on a rotation speed of the laminated substrates Ws by the substrate holding device 2 and the detected position of the application target point Tp.

The position detecting device 5 (the edge-shape detector 40 in this embodiment) is configured to detect position information on multiple application target points Tp arranged along the circumferential direction of the laminated substrate Ws when being rotated. The edge-shape detector 40 detects the shape of the edge portion of the laminated substrate Ws at predetermined time intervals when the laminated substrate Ws is rotated to thereby detect multiple shapes of the edge portion of the laminated substrate Ws along the circumferential direction of the laminated substrate Ws. According to such operations, the edge-shape detector 40 detects the position information on the multiple application target points Tp arranged along the circumferential direction of the laminated substrate Ws.

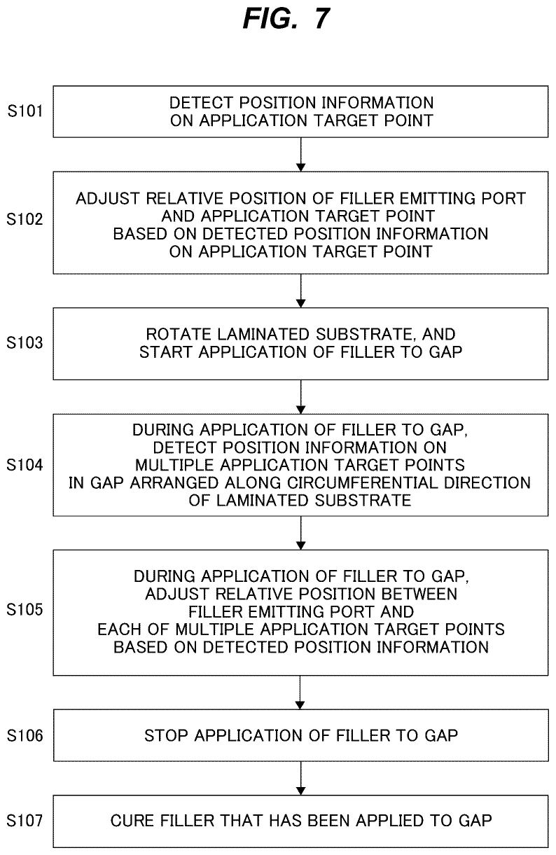

FIG. 7 is a flowchart illustrating an embodiment of a method of manufacturing the laminated structure.

In step S101, the position detecting device 5 detects position information on an application target point Tp before application of the filler F to the gap G of the laminated substrate Ws is started. In this embodiment, the edge-shape detector 40 detects the position information on the application target point Tp by detecting a shape of the edge portion of the laminated substrate Ws. The position information on the application target point Tp detected by the position detecting device 5 is transmitted to the operation controller 10.

In step S102, the operation controller 10 instructs the application-device moving mechanism 30 to adjust a relative position of the filler emitting port 21a of the application device 3 and the application target point Tp based on the position information on the application target point Tp detected by the position detecting device 5 (the edge-shape detector 40 in this embodiment) such that the relative position of the filler emitting port 21a and the application target point Tp coincides with a target relative position. As a result, the application device 3 can be arranged at an appropriate application starting position.

In step S103, the operation controller 10 instructs the substrate holding device 2 to rotate the laminated substrate Ws, and instructs the pressure regulator 26 to cause the filler emitting port 21a of the application device 3 to emit the filler F therefrom, so that application of the filler F to the gap G of the laminated substrate Ws is started.

In step S104, during application of the filler F to the gap G of the laminated substrate Ws, the position detecting device 5 detects position information on multiple application target points Tp in the gap G arranged along the circumferential direction of the laminated substrate Ws. In this embodiment, the edge-shape detector 40 detects position information on the multiple application target points Tp by detecting multiple shapes of the edge portion of the laminated substrate Ws along the circumferential direction of the laminated substrate Ws during application of the filler F to the gap G of the laminated substrate Ws. The position information on the multiple application target points Tp detected by the position detecting device 5 are transmitted to the operation controller 10.

In step S105, during application of the filler F to the gap G of the laminated substrate Ws, the operation controller 10 instructs the application-device moving mechanism 30 (i.e., the first application-device moving mechanism 31 and the second application-device moving mechanism 32) to adjust a relative position between the filler emitting port 21a and each of the multiple application target points Tp such that the relative position between the filler emitting port 21a and each of the multiple application target points Tp coincides with the target relative position, based on the position information on the multiple application target points Tp detected by the position detecting device 5 (the edge-shape detector 40 in this embodiment). The operation controller 10 determines (calculates) timings to cause the application-device moving mechanism 30 (i.e., the first application-device moving mechanism 31 and the second application-device moving mechanism 32) to move the application device 3 based on the rotation speed of the laminated substrate Ws rotated by the substrate holding device 2 and the detected positions of the application target points Tp.

During application of the filler F to the gap G of the laminated substrate Ws, the step S104 (i.e., detection of the position information on the application target points Tp) and the step S105 (i.e., adjustment of the relative positions of the filler emitting port 21a and the application target points Tp) are performed in parallel. The operation controller 10 sequentially causes the application-device moving mechanism 30 (i.e., the first application-device moving mechanism 31 and the second application-device moving mechanism 32) to adjust the relative positions of the filler emitting port 21a and the application target points Tp based on the position information on the application target points Tp that are sequentially detected. As a result, during application of the filler F to the gap G of the laminated substrate Ws, the relative position of the filler emitting port 21a and each of the multiple application target points Tp is maintained at the target relative position, so that the position of the filler emitting port 21a can follow the multiple application target points Tp.

In step S106, the operation controller 10 instructs the pressure regulator 26 to cause the application device 3 to stop the application of the filler F to the gap G.

In step S107, the operation controller 10 instructs the curing device 4 to cure the filler F that has been applied to the gap G of the laminated substrate Ws. In one embodiment, the curing of the filler F by the curing device 4 may be performed while the filler F is being applied by the application device 3.

According to this embodiment, the relative position of the filler emitting port 21a of the application device 3 and the application target point Tp is adjusted based on the position information on the application target points Tp detected by the position detecting device 5. As a result, the relative position of the filler emitting port 21a and the application target point Tp can be maintained at the predetermined target relative position, so that the filler F can be appropriately applied to the gap G between the edge portion E1 of the first substrate W1 and the edge portion E2 of the second substrate W2.

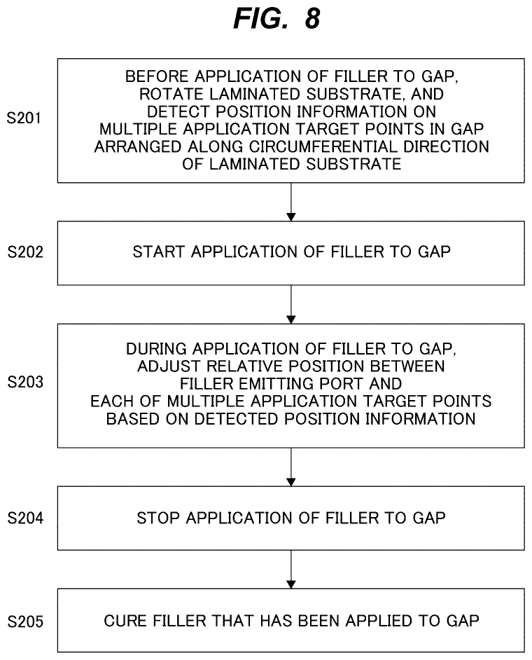

FIG. 8 is a flowchart illustrating another embodiment of the method of manufacturing the laminated structure.

In step S201, the operation controller 10 instructs the substrate holding device 2 to rotate the laminated substrate Ws. While the laminated substrate Ws is rotated, the position detecting device 5 detects position information on multiple application target points Tp in the gap G arranged along the circumferential direction of the laminated substrate Ws. In this embodiment, the edge-shape detector 40 detects the position information on the multiple application target points Tp by detecting multiple shapes of the edge portion of the laminated substrate Ws. The position information on the multiple application target points Tp detected by the position detecting device 5 are transmitted to the operation controller 10.

In step S202, the operation controller 10 instructs the pressure regulator 26 to cause the filler emitting port 21a of the application device 3 to emit the filler F therefrom, so that application of the filler F to the gap G of the laminated substrate Ws is started.

In step S203, during application of the filler F to the gap G of the laminated substrate Ws, the operation controller 10 instructs the application-device moving mechanism 30 (i.e., the first application-device moving mechanism 31 and the second application-device moving mechanism 32) to adjust a relative position between the filler emitting port 21a and each of the multiple application target points Tp such that the relative position between the filler emitting port 21a and each of the multiple application target points Tp coincides with a target relative position, based on the position information on the multiple application target points Tp detected by the position detecting device 5 (the edge-shape detector 40 in this embodiment) in the step S201. The operation controller 10 controls timings to cause the application-device moving mechanism 30 (i.e., the first application-device moving mechanism 31 and the second application-device moving mechanism 32) to move the application device 3 based on the rotation speed of the laminated substrate Ws rotated by the substrate holding device 2 and the detected positions of the application target points Tp.

As a result, during application of the filler F to the gap G of the laminated substrate Ws, the relative position between the filler emitting port 21a and each of the multiple application target points Tp is maintained at the target relative position, so that the position of the filler emitting port 21a can follow the multiple application target points Tp.

In step S204, the operation controller 10 instructs the pressure regulator 26 to cause the application device 3 to stop the application of the filler F to the gap G.

In step S205, the operation controller 10 instructs the curing device 4 to cure the filler F that has been applied to the gap G of the laminated substrate Ws. In one embodiment, the curing of the filler F by the curing device 4 may be performed while the filler F is being applied by the application device 3.

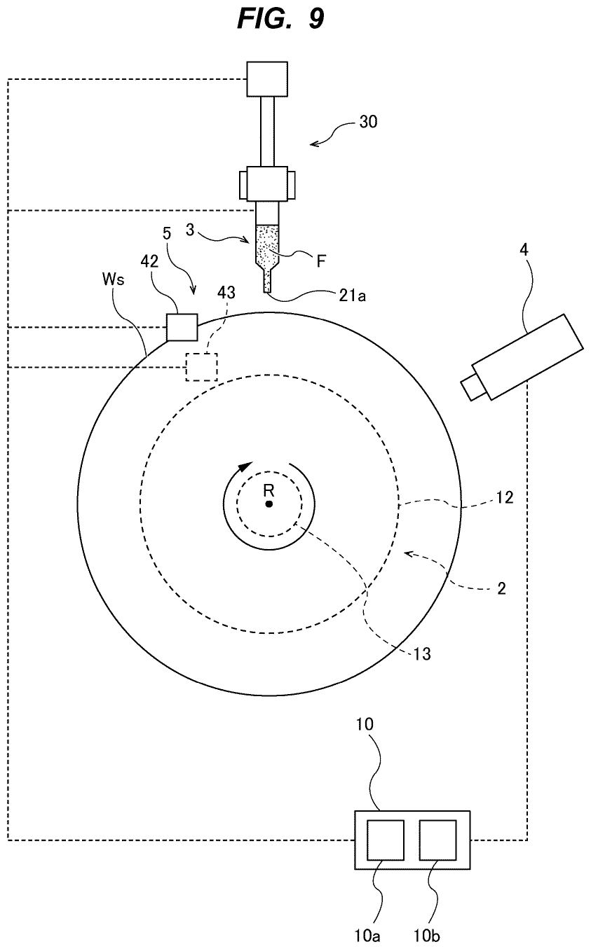

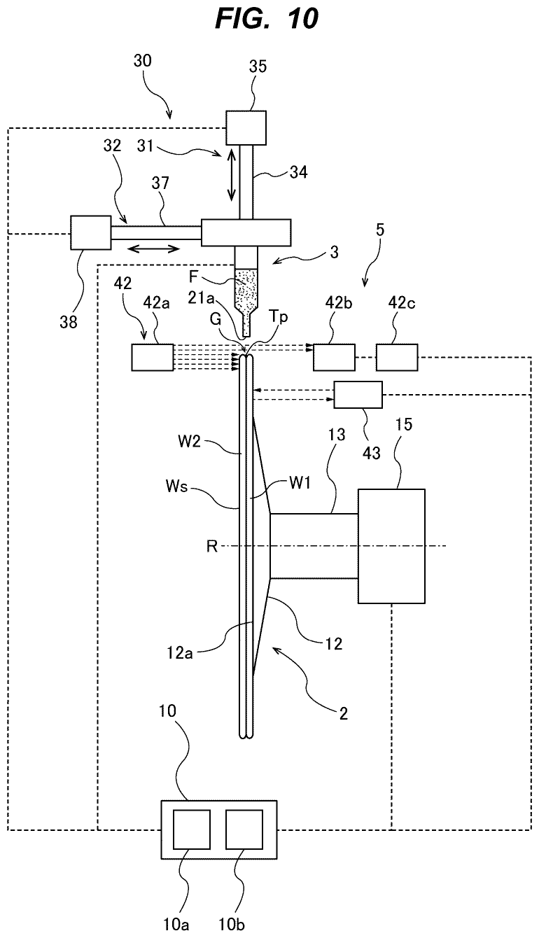

FIG. 9 is a front view showing another embodiment of the laminated-structure manufacturing apparatus, and FIG. 10 is a side view of the laminated-structure manufacturing apparatus shown in FIG. 9. Configurations and operations of this embodiment, which will be not particularly described, are the same as those of the above-described embodiment, and duplicated descriptions will be omitted. The position detecting device 5 of this embodiment includes, instead of the edge-shape detector 40, an eccentricity detector 42 configured to detect a position of the application target point Tp in the radial direction of the laminated substrate Ws, and a surface-deflection detector 43 configured to detect a position of the application target point Tp in the thickness direction of the laminated substrate Ws.

As shown in FIG. 9, the eccentricity detector 42 and the surface-deflection detector 43 are disposed upstream of the application device 3 in the rotating direction of the laminated substrate Ws. Positions of the eccentricity detector 42 and the surface-deflection detector 43 are fixed. The eccentricity detector 42 and the surface-deflection detector 43 are configured to detect position information on the application target point Tp when the application target point Tp is located upstream of the filler emitting port 21a of the application device 3 in the rotating direction of the laminated substrate Ws.

As shown in FIG. 10, the eccentricity detector 42 has a light emitter 42a and a light receiver 42b arranged symmetrically with respect to the edge portion of the laminated substrate Ws, and a signal processor 42c coupled to the light receiver 42b. Light emitted from the light emitter 42a is received by the light receiver 42b. Since a part of the light emitted from the light emitter 42a is blocked by the edge portion of the laminated substrate Ws, an amount of the light received by the light receiver 42b varies depending on the radial position of the laminated substrate Ws. The signal processor 42c determines (calculates) a position of the edge portion in the radial direction of the laminated substrate Ws based on the amount of the light received by the light receiver 42b. Since a relative position of the application target point Tp with respect to the edge portion of the laminated substrate Ws is fixed, the eccentricity detector 42 can detect the position of the application target point Tp in the radial direction of the laminated substrate Ws from the position of the edge portion of the laminated substrate Ws.

The surface-deflection detector 43 is arranged so as to face the back surface of the laminated substrate Ws (i.e., a non-bonding surface of the first substrate W1). The surface-deflection detector 43 has a light source (not shown), and a light-receiving element (not shown). The surface-deflection detector 43 directs light from the light source to the back surface of the laminated substrate Ws, and receives reflected light from the back surface of the laminated substrate Ws by the light-receiving element. The surface-deflection detector 43 determines (calculates) a position of the back surface of the laminated substrate Ws based on the reflected light. Since a relative position of the application target point Tp with respect to the back surface of the laminated substrate Ws is fixed, the surface-deflection detector 43 can detect the position of the application target point Tp in the thickness direction of the laminated substrate Ws from the position of the back surface of the laminated substrate Ws. Examples of the surface-deflection detector 43 include a displacement sensor, a position sensor, and a distance sensor. In one embodiment, the surface-deflection detector 43 may be arranged so as to face a front surface of the laminated substrate Ws (i.e., a non-bonding surface of the second substrate W2), and may detect the position of the application target point Tp from a position of the front surface of the laminated substrate Ws.

The eccentricity detector 42 and the surface-deflection detector 43 are electrically coupled to the operation controller 10. The position of the application target point Tp in the radial direction of the laminated substrate Ws detected by the eccentricity detector 42 and the position of the application target point Tp in the thickness direction of the laminated substrate Ws detected by the surface-deflection detector 43 are transmitted to the operation controller 10. The operation controller 10 instructs the application-device moving mechanism 30 (the first application-device moving mechanism 31 and the second application-device moving mechanism 32 in this embodiment) to adjust the relative position of the filler emitting port 21a of the application device 3 and the application target point Tp such that the relative position of the filler emitting port 21a of the application device 3 and the application target point Tp coincides with the predetermined target relative position, based on the detected position information on the application target point Tp.

In this embodiment, just before the application target point Tp is located directly below the filler emitting port 21a of the application device 3, the operation controller 10 instructs the application-device moving mechanism 30 (i.e., the first application-device moving mechanism 31 and the second application-device moving mechanism 32) to move the application device 3 based on the position information on the application target point Tp detected by the eccentricity detector 42 and the surface-deflection detector 43. The operation controller 10 determines (calculates) a timing to cause the application-device moving mechanism 30 (i.e., the first application-device moving mechanism 31 and the second application-device moving mechanism 32) to move the application device 3 based on the rotation speed of the laminated substrates Ws rotated by the substrate holding device 2 and the detected position of the application target point Tp.

The position detecting device 5 (the eccentricity detector 42 and the surface-deflection detector 43 in this embodiment) is configured to detect position information on multiple application target points Tp arranged along the circumferential direction of the laminated substrate Ws when being rotated. The eccentricity detector 42 detects the position of the application target point Tp in the radial direction of the laminated substrate Ws at predetermined time intervals when the laminated substrate Ws is rotated to thereby detect positions of the multiple application target points Tp arranged along the circumferential direction of the laminated substrate Ws in the radial direction of the laminated substrate Ws. The surface-deflection detector 43 detects the position of the application target points Tp in the thickness direction of the laminated substrate Ws at predetermined time intervals when the laminated substrate Ws is rotated to thereby detect positions of the multiple application target points Tp arranged along the circumferential direction of the laminated substrate Ws in the thickness direction of the laminated substrate Ws.

The embodiment described with reference to FIGS. 9 and 10 can be applied to the methods of manufacturing the laminated structure shown in FIGS. 7 and 8.

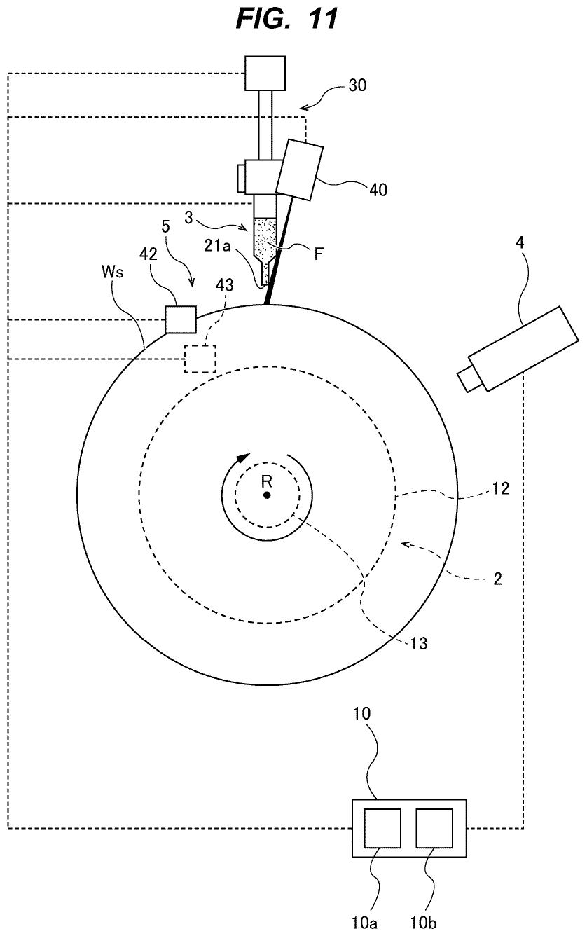

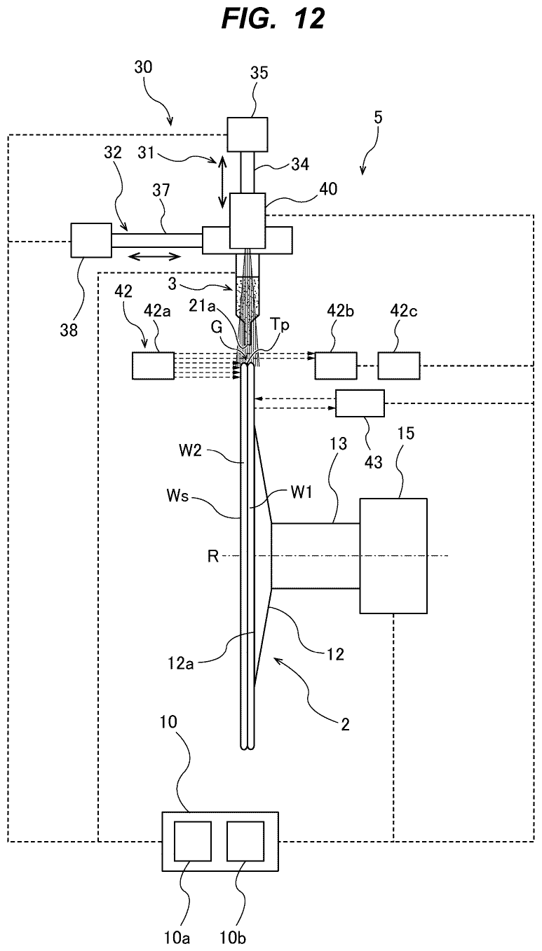

FIG. 11 is a side view showing still another embodiment of the laminated-structure manufacturing apparatus, and FIG. 12 is a front view of the laminated-structure manufacturing apparatus shown in FIG. 11. Configurations and operations of this embodiment, which will be not particularly described, are the same as those of the embodiment described with reference to FIGS. 9 and 10, and duplicated descriptions will be omitted. The position detecting device 5 of this embodiment further includes the edge-shape detector 40 in addition to the eccentricity detector 42 and the surface-deflection detector 43.

As shown in FIG. 11, the edge-shape detector 40 is arranged adjacent to the application device 3, and is arranged above the laminated substrate Ws. The eccentricity detector 42 and the surface-deflection detector 43 are disposed upstream of the application device 3 in the rotating direction of the laminated substrate Ws. Positions of the edge-shape detector 40, the eccentricity detector 42, and the surface-deflection detector 43 are fixed. The edge-shape detector 40 is configured to detect the position information on the application target point Tp when the application target point Tp is located at the same position as the filler emitting port 21a of the application device 3 in the rotating direction of the laminated substrate Ws (when the application target point Tp is located close to the filler emitting port 21a of the application device 3). The eccentricity detector 42 and the surface-deflection detector 43 are configured to detect the position information on the application target point Tp when the application target point Tp is located upstream of the filler emitting port 21a of the application device 3 in the rotating direction of the laminated substrate Ws.

The laminated-structure manufacturing apparatus of this embodiment can be applied to the method of manufacturing the laminated structure shown in FIG. 7. The step S101 shown in FIG. 7 (i.e., detecting of the position information on the application target point Tp before application of the filler F is started) is performed by the edge-shape detector 40. The edge-shape detector 40 detects the position information on the application target point Tp when the application target point Tp is located at the same position as the filler emitting port 21a of the application device 3 in the rotating direction of the laminated substrate Ws (when the application target point Tp is located close to the filler emitting port 21a of the application device 3). The step S104 (i.e., detecting of the position information on the multiple application target points Tp in the gap G arranged along the circumferential direction of the laminated substrate Ws during application of the filler F to the gap G of the laminated substrate Ws) is performed by the eccentricity detector 42 and the surface-deflection detector 43.

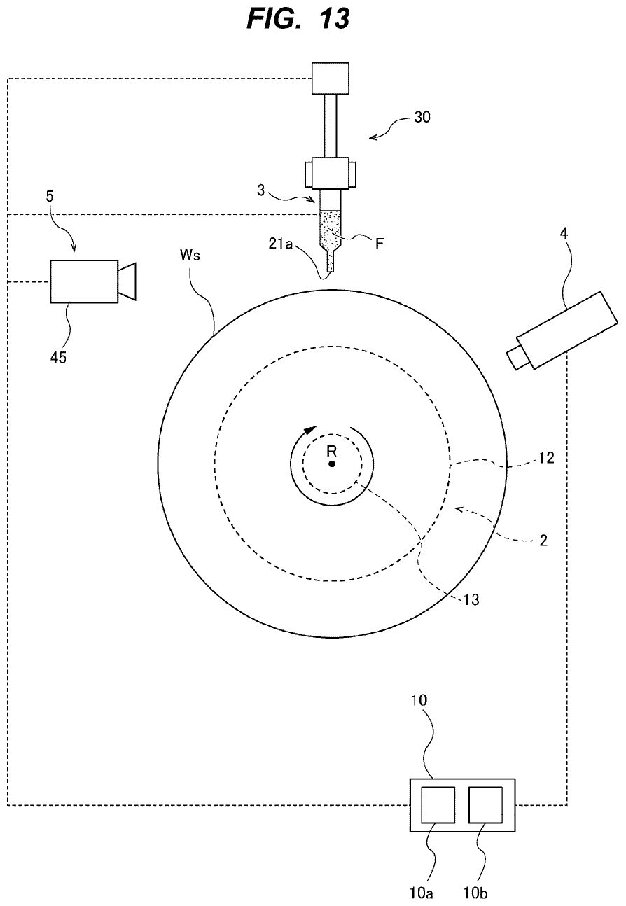

FIG. 13 is a front view showing still another embodiment of the laminated-structure manufacturing apparatus. Configurations and operations of this embodiment, which will be not particularly described, are the same as those of the embodiment described with reference to FIGS. 2 and 3, and duplicated descriptions will be omitted. The position detecting device 5 of this embodiment includes, instead of the edge-shape detector 40, an image generating device 45 configured to generate an image of the edge portion of the laminated substrate Ws.

As shown in FIG. 13, the image generating device 45 is located upstream of the application device 3 in the rotating direction of the laminated substrate Ws, and is arranged laterally of the laminated substrate Ws. The image generating device 45 is configured to generate an image of the edge portion of the laminated substrate Ws. The image generating device 45 includes a not-shown image sensor (e.g., a CMOS sensor or a CCD sensor).

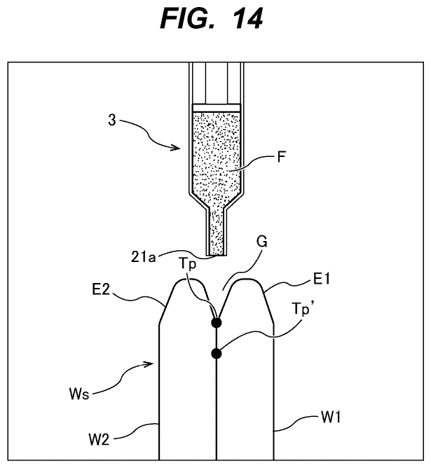

FIG. 14 is a diagram showing an example of the image of the edge portion of the laminated substrate Ws generated by the image generating device 45. As shown in FIG. 14, the image of the edge portion of the laminated substrate Ws includes an image of a valley representing the gap G between the edge portion E1 of the first substrate Ws and the edge portion E2 of the second substrate W2. Therefore, information on the position of the application target point Tp in the radial direction of the laminated substrate Ws and the position of the application target point Tp in the thickness direction of the laminated substrate Ws are included in the generated image of the edge portion of the laminated substrate Ws. In this manner, the image generating device 45 detects the position information on the application target point Tp (i.e., the position of the application target point Tp in the radial direction of the laminated substrate Ws and the position of the application target point Tp in the thickness direction of the laminated substrate Ws). In this embodiment, the application target point Tp is the deepest portion of the gap G appearing in the image of the edge portion of the laminated substrate Ws, while in one embodiment, the application target point Tp may be the midpoint in the thickness direction of the laminated substrate Ws appearing in the image of the edge portion of the laminated substrate Ws.

As shown in FIG. 13, the image generating device 45 is electrically coupled to the operation controller 10. The position information on the application target point Tp (i.e., the position of the application target point Tp in the radial direction of the laminated substrate Ws and the position of the application target point Tp in the thickness direction of the laminated substrate Ws included in the image of the edge portion of the laminated substrate Ws) detected by the image generating device 45 is transmitted to the operation controller 10. The operation controller 10 instructs the application-device moving mechanism 30 to adjust the relative position of the filler emitting port 21a of the application device 3 and the application target point Tp such that the relative position of the filler emitting port 21a and the application target point Tp coincides with the predetermined target relative position, based on the detected position information on the application target point Tp.

As shown in FIG. 14, the image generating device 45 may be configured to generate an image in which both the edge portion of the laminated substrate Ws and the filler emitting port 21a of the application device 3 appear, and may be configured to detect position information on the filler emitting port 21a in addition to the position information on the application target point Tp. The position information on the application target point Tp and the position information on the filler emitting port 21a detected by the image generating device 45 are transmitted to the operation controller 10. The operation controller 10 may be configured to instruct the application-device moving mechanism 30 to adjust the relative position of the filler emitting port 21a and the application target point Tp until the relative position of the filler emitting port 21a and the application target point Tp coincides with the predetermined target relative position based on the position information on the application target point Tp and the position information on the filler emitting port 21a transmitted from the image generating device 45.

The image generating device 45 may detect the position information on the application target point Tp when the application target point Tp is located at the same position as the filler emitting port 21a of the application device 3 in the rotating direction of the laminated substrate Ws (when the application target point Tp is located close to the filler emitting port 21a of the application device 3). Alternatively, the image generating device 45 may detect the position information on the application target point Tp when the application target point Tp is located upstream of the filler emitting port 21a of the application device 3 in the rotating direction of the laminated substrate Ws (indicated by a symbol Tp′ in FIG. 14). The operation controller 10 determines (calculates) a timing to cause the application-device moving mechanism 30 to move the application device 3 based on the rotation speed of the laminated substrate Ws rotated by the substrate holding device 2 and the detected position of the application target point Tp.

The position detecting device 5 (the image generating device 45 in this embodiment) is configured to detect position information on multiple application target points Tp arranged along the circumferential direction of the laminated substrate Ws when the laminated substrate Ws is being rotated. The image generating device 45 generates multiple images of the edge portion of the laminated substrate Ws along the circumferential direction of the laminated substrate Ws at predetermined time intervals when the laminated substrate Ws is rotated. In this manner, the image generating device 45 detects the position information on the multiple application target points Tp arranged along the circumferential direction of the laminated substrate Ws.

In one embodiment, the laminated-structure manufacturing apparatus may include an input device (not shown), such as a keyboard, a mouse, etc., and a display device (not shown), such as a display, configured to display the image of the edge portion of the laminated substrate Ws generated by the image generating device 45. An operator may select an arbitrary point on the image displayed on the display device as the application target point Tp, and may input the application target point Tp with the input device. The input device and the display device are electrically coupled to the operation controller 10. The operation controller 10 may instruct the application-device moving mechanism 30 to adjust the relative position of the filler emitting port 21a of the application device 3 and the application target point Tp based on the input position information on the application target point Tp such that the relative position of the filler emitting port 21a and the application target point Tp coincides with the predetermined target relative position.

The embodiment described with reference to FIGS. 13 and 14 can be applied to the methods of manufacturing the laminated structure shown in FIGS. 7 and 8.

In one embodiment, the image generating device 45 may be configured to generate an image of the filler F being emitted (falling) from the filler emitting port 21a during application of the filler F to the gap G of the laminated substrate Ws. In this case, the operation controller 10 may be configured to judge an emitting condition of the filler F based on the image of the filler F being emitted (falling) from the filler emitting port 21a generated by the image generating device 45.

Specifically, the operation controller 10 may be configured to judge that the emitting condition of the filler F is normal when the filler F being emitted (falling) from the filler emitting port 21a toward the application target point Tp appears in the image. The operation controller 10 may be configured to judge that the emitting condition of the filler F is abnormal when the filler F being emitted from the filler emitting port 21a toward the application target point Tp does not appear in the image (e.g., when the filler F being emitted obliquely from the filler emitting port 21a appears in the image). Further, the operation controller 10 may be configured to stop the application of the filler F by the application device 3 when the operation controller 10 judges that the emitting condition of the filler F is abnormal.

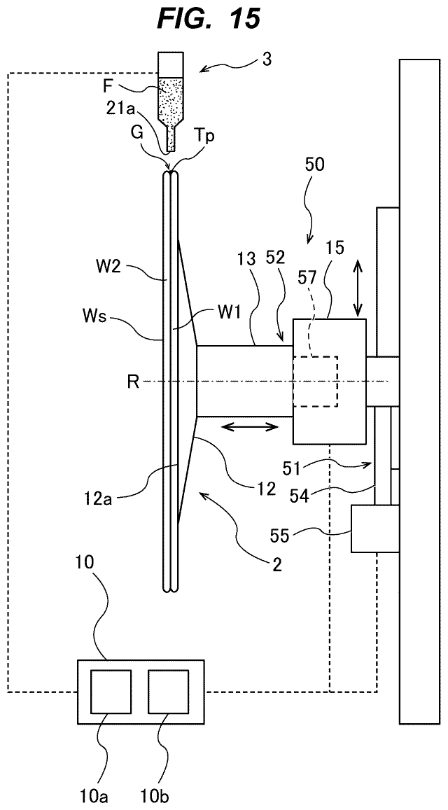

The laminated-structure manufacturing apparatus in the above-described embodiments includes the application-device moving mechanism 30 that moves the application device 3 as the relative moving mechanism, while in one embodiment, the laminated-structure manufacturing apparatus may include, as the relative moving mechanism, a substrate moving mechanism 50 configured to move the laminated substrate Ws held by the substrate holding device 2. FIG. 15 is a side view showing an embodiment of the laminated-structure manufacturing apparatus including the substrate moving mechanism 50. The substrate moving mechanism 50 includes a first substrate moving mechanism 51 configured to move the laminated substrate Ws in the radial direction thereof, and a second substrate moving mechanism 52 configured to move the laminated substrate Ws in the thickness direction thereof. The first substrate moving mechanism 51 and the second substrate moving mechanism 52 are coupled to the substrate holding device 2.

The first substrate moving mechanism 51 is configured to move the substrate holding device 2 in the direction perpendicular to the rotation axis R of the substrate holding device 2. The second substrate moving mechanism 52 is configured to move the substrate holding device 2 in the direction parallel to the rotation axis R of the substrate holding device 2. Examples of the first substrate moving mechanism 51 and the second substrate moving mechanism 52 include a combination of a linear moving mechanism (such as a ball screw mechanism or a cylinder mechanism) and a motor (such as a servo motor or a stepping motor), and a linear moving electric actuator (such as a linear motor).

The first substrate moving mechanism 51 of this embodiment includes a first linear moving mechanism 54 coupled to the substrate holding device 2, and a first motor 55 coupled to the first linear moving mechanism 54. The first motor 55 and the first linear moving mechanism 54 are configured to move the entire substrate holding device 2 in the radial direction of the laminated substrate Ws, so that the laminated substrate Ws held by the substrate holding device 2 is moved in the radial direction of the laminated substrate Ws. More specifically, the first motor 55 is configured to actuate the first linear moving mechanism 54 to thereby move the gap G of the laminated substrate Ws toward and away from the filler emitting port 21a of the application device 3. The second substrate moving mechanism 52 of this embodiment includes a second motor 57 coupled to the rotating shaft 13 of the substrate holding device 2. The second motor 57 is configured to move the holding stage 12 in the thickness direction of the laminated substrate Ws via the rotating shaft 13, so that the laminated substrate Ws held by the substrate holding device 2 is moved in the thickness direction of the laminated substrate Ws.

The substrate moving mechanism 50 (i.e., the first substrate moving mechanism 51 and the second substrate moving mechanism 52) is electrically coupled to the operation controller 10. Operations of the substrate moving mechanism 50 (i.e., the first substrate moving mechanism 51 and the second substrate moving mechanism 52) are controlled by the operation controller 10. In this embodiment, the first substrate moving mechanism 51 is coupled to the substrate holding device 2 via the second substrate moving mechanism 52, while in one embodiment, the second substrate moving mechanism 52 may be coupled to the substrate holding device 2 via the first substrate moving mechanism 51.

The operation controller 10 is configured to instruct the substrate moving mechanism 50 (i.e., the first substrate moving mechanism 51 and the second substrate moving mechanism 52) to adjust the relative position of the filler emitting port 21a of the application device 3 and the application target point Tp such that the relative position of the filler emitting port 21a of the application device 3 and the application target point Tp coincides with the predetermined target relative position, based on the position information on the application target point Tp detected by the position detecting device 5.

More specifically, the operation controller 10 is configured to determine a current position of the application target point Tp based on the position information on the application target point Tp detected by the position detecting device 5, and is configured to calculate a distance and a direction (i.e., a vector) from the current position of the application target point Tp to a reference position of the application target point Tp. Further, the operation controller 10 is configured to instruct the substrate moving mechanism 50 (i.e., the first substrate moving mechanism 51 and the second substrate moving mechanism 52) to move the laminated substrate Ws held by the substrate holding device 2 by the calculated distance in the calculated direction. According to such operations, the relative position of the filler emitting port 21a and the application target point Tp is maintained at the predetermined target relative position. The target relative position is a relative position at which the filler F is appropriately applied from the filler emitting port 21a to the gap G of the laminated substrate Ws, and is determined in advance based on experimental results, etc.

The adjustment of the relative position of the filler emitting port 21a and the application target point Tp by the substrate moving mechanism 50 (i.e., the first substrate moving mechanism 51 and the second substrate moving mechanism 52) can be applied to each of the above-described embodiments, instead of the adjustment of the relative position of the filler emitting port 21a and the application target point Tp by the application-device moving mechanism 30 (i.e., the first application-device moving mechanism 31 and the second application-device moving mechanism 32).

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### Industrial Applicability

The present invention is applicable to a laminated-structure manufacturing apparatus and a method of manufacturing a laminated structure for suppressing cracking and chipping of a laminated substrate manufactured by bonding substrates, and more particularly to a technique of applying filler to a gap between edge portions of the substrates constituting the laminated substrate.

### REFERENCE SIGNS LIST

2 substrate holding device
3 application device
4 curing device
5 position detecting device
10 operation controller
10a memory
10b processor
12 holding stage
12a holding surface
13 rotating shaft
15 rotating mechanism
21 syringe
21a filler emitting port
22 piston
25 gas supply line
26 pressure regulator
30 application-device moving mechanism (relative moving mechanism)
31 first application-device moving mechanism
32 second application-device moving mechanism
34 first linear moving mechanism
35 first motor
37 second linear moving mechanism
38 second motor
40 edge-shape detector
42 eccentricity detector
42a light emitter
42b light receiver
42c signal processor
43 surface-deflection detector
45 image generating device
50 substrate moving mechanism (relative moving mechanism)
51 first substrate moving mechanism
52 second substrate moving mechanism
54 first linear moving mechanism
55 first motor
57 second motor
E1, E2 edge portion
F filler
G gap
Tp application target point
W1 first substrate
W2 second substrate
Ws laminated substrate

1. A laminated-structure manufacturing apparatus for applying filler to a laminated substrate having a first substrate and a second substrate bonded to each other to manufacture a laminated structure, comprising:
a substrate holding device configured to hold and rotate the laminated substrate;
an application device configured to apply the filler to a gap between an edge portion of the first substrate and an edge portion of the second substrate, the application device having a filler emitting port configured to emit the filler;
a relative moving mechanism configured to move at least one of the application device and the substrate holding device;
a position detecting device configured to detect position information on an application target point in the gap; and
an operation controller configured to instruct the relative moving mechanism to adjust a relative position of the filler emitting port and the application target point based on the detected position information.

2. The laminated-structure manufacturing apparatus according to claim 1, wherein the position detecting device is configured to detect the position information including a position of the application target point in a radial direction of the laminated substrate and a position of the application target point in a thickness direction of the laminated substrate.

3. The laminated-structure manufacturing apparatus according to claim 2, wherein the position detecting device includes an edge-shape detector configured to detect a shape of an edge portion of the laminated substrate.

4. The laminated-structure manufacturing apparatus according to claim 2, wherein the position detecting device includes an eccentricity detector configured to detect the position of the application target point in the radial direction of the laminated substrate, and a surface-deflection detector configured to detect the position of the application target point in the thickness direction of the laminated substrate.

5. The laminated-structure manufacturing apparatus according to claim 2, wherein the position detecting device includes an image generating device configured to generate an image of an edge portion of the laminated substrate.

6. The laminated-structure manufacturing apparatus according to claim 1, wherein
the position detecting device is configured to detect position information on multiple application target points in the gap arranged along a circumferential direction of the laminated substrate, and
the operation controller is configured to instruct the relative moving mechanism to adjust a relative position of the filler emitting port and each of the multiple application target points based on the detected position information during application of the filler to the gap of the laminated substrate when the laminated substrate is rotated.

7. The laminated-structure manufacturing apparatus according to claim 1, wherein the position detecting device is configured to detect the position information on the application target point when the application target point is located upstream of the filler emitting port in a rotating direction of the laminated substrate.

8. A method of manufacturing a laminated structure by applying filler to a laminated substrate having a first substrate and a second substrate bonded to each other, comprising:
detecting position information on an application target point in a gap between an edge portion of the first substrate and an edge portion of the second substrate;
adjusting a relative position of a filler emitting port configured to emit the filler and the application target point based on the detected position information; and
applying the filler to the gap while the laminated substrate is rotated.

9. The method of manufacturing the laminated structure according to claim 8, wherein detecting the position information comprises detecting the position information including a position of the application target point in a radial direction of the laminated substrate and a position of the application target point in a thickness direction of the laminated substrate.

10. The method of manufacturing the laminated structure according to claim 9, wherein detecting the position information includes detecting a shape of an edge portion of the laminated substrate by an edge-shape detector.

11. The method of manufacturing the laminated structure according to claim 9, wherein detecting the position information includes detecting the position of the application target point in the radial direction of the laminated substrate by an eccentricity detector, and detecting the position of the application target point in the thickness direction of the laminated substrate by a surface-deflection detector.

12. The method of manufacturing the laminated structure according to claim 9, wherein detecting the position information includes generating an image of an edge portion of the laminated substrate by an image generating device.

13. The method of manufacturing the laminated structure according to claim 8, wherein
detecting the position information comprises detecting position information on multiple application target points in the gap arranged along a circumferential direction of the laminated substrate when each of the multiple application target points is located upstream of the filler emitting port in a rotating direction of the laminated substrate during application of the filler to the gap, and
adjusting the relative position comprises adjusting a relative position of the filler emitting port and each of the multiple application target points based on the detected position information during application of the filler to the gap.

14. The method of manufacturing the laminated structure according to claim 8, wherein
detecting the position information comprises detecting position information on multiple application target points in the gap arranged along a circumferential direction of the laminated substrate while the laminated substrate is rotated before the filler is applied to the gap, and
adjusting the relative position comprises adjusting a relative position of the filler emitting port and each of the multiple application target points based on the detected position information during application of the filler to the gap.
